(19) United States
(12) Patent Application Publication
(10) Pub. No.: US 2009/0230472 A1
(43) Pub. Date: Sep. 17, 2009

(54) Semiconductor Device Having a Floating Body Transistor and Method for Manufacturing the Same

(75) Inventor: Su Ock Chung, Seoul (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/199,001

(22) Filed: Aug. 27, 2008

(30) Foreign Application Priority Data
Mar. 13, 2008 (KR) 10-2008-0023554

(51) Int. Cl. H01L 29/786; H01L 21/336

(52) U.S. Cl. 257/347; 438/151; 257/E29.273; 257/E21.411

(57) ABSTRACT

A method for manufacturing a semiconductor device that has a floating body transistor may include: etching a SOI substrate to expose a BOX region, epitaxially growing sidewalls of the substrate and contacting the grown silicon to a landing plug poly to form source/drain regions. The method reduces the occurrence of a punch-through phenomenon between the source and the drain without decreasing the thickness of the SOI substrate, and also facilitates junction isolation.

### CROSS-REFERENCE TO RELATED APPLICATION

The priority benefit of Korean patent application number 10-2008-0023554, filed on Mar. 13, 2008, is hereby claimed and the disclosure thereof is incorporated herein by reference in its entirety.

### BACKGROUND OF THE INVENTION

This patent relates to a semiconductor device having a floating body transistor and a method for manufacturing the same.

High-integration, high-speed operation, and low power consumption of semiconductor devices have driven designs using a Silicon-On-Insulation (SOI) substrate instead of a bulk silicon substrate.

In comparison with a device formed in the bulk silicon substrate, the device formed in the SOI substrate has high operating speed due to small junction capacitance, requires a low voltage due to a low threshold voltage and removes latch-up by complete device isolation.

FIGS. 1a to 1d are cross-sectional diagrams illustrating a conventional method for forming a cell array type floating body transistor using a SOI substrate.

Referring to FIG. 1a, a device isolation film 14 for device isolation is formed over a SOI substrate 13 including a lower silicon substrate 11, a buried insulating film (SiO2) (BOX region) 12 and an upper silicon substrate 13. A gate electrode 15 including a hard mask is formed over an active region defined by the device isolation film 14.

Referring to FIG. 1b, a nitride film for forming a spacer 16 and an oxide film for forming an interlayer insulating (ILD) layer 17 are sequentially formed over the resulting structure of FIG. 1a. The oxide film and the nitride film where a landing plug contact (LPC) is to be formed are etched. As a result, a spacer 16 is formed on sidewalls of the gate electrode 15. The surface of the silicon substrate 13 exposed between the gate electrodes 15 is etched at a given depth.

Referring to FIG. 1c, impurities (e.g., N+) are ion-implanted into the silicon substrate 13 exposed between gate electrodes 15 to form source/drain region 18.

Referring to FIG. 1d, a landing plug poly 19 is formed over the resulting structure of FIG. 1c, and planarized to expose the gate electrode 15.

In the above-described way, since a floating body transistor formed in the SOI substrate has a floating body effect in proportion to the volume of the SOI substrate 13, it is undesirable to apply a recess gate structure to the SOI substrate 13 for securing a cell operating margin. As a result, it is difficult to prevent a punch-through phenomenon in the area between the source and the drain of the transistor, which becomes smaller.

When the floating body transistor formed in the SOI substrate is configured to have a cell array type, the landing plug poly 19 is formed and annealed at a high temperature so that the source/drain junction region may be diffused into the BOX 12 as shown in FIG. 1d, thereby isolating the junction between cells.

However, when the junction region is diffused into the box region, BOX 12, the junction region is also diffused horizontally leading to the punch-through phenomenon between the source and the drain. Particularly, as the cell size becomes smaller, and hence the area between the source and the drain becomes smaller, the punch-through phenomenon occurs more frequently.

In order to prevent the punch-through phenomenon in the conventional construction, the thickness of the SOI substrate is reduced as the cell size becomes smaller.

However, when the thickness of the SOI substrate is reduced, the amount of hole charges accumulated in the floating body is decreased. That is, the floating body effect is decreased, thereby reducing the operating margin of the device.

### SUMMARY OF THE INVENTION

Various embodiments of the present invention are directed at preventing a punch-through phenomenon between a source and a drain and at facilitating junction isolation without decreasing the thickness of a SOI substrate.

According to an embodiment of the present invention, a method for manufacturing a semiconductor device may include: etching a Silicon-On-Insulation (SOI) substrate of source/drain regions to expose a BOX region; growing sidewalls of the etched substrate in a direction; and filling a landing plug poly between the grown sidewalls.

According to another embodiment of the present invention, a method for manufacturing a semiconductor device may include: forming a gate electrode over a SOI substrate; forming a spacer on sidewalls of the gate electrode; etching the substrate between the gate electrodes exposed by the spacer to expose a BOX region; growing sidewalls of the etched substrate; and filling a landing plug poly between the grown the sidewalls.

The method may further include annealing the landing plug poly at low temperature.

The growing a substrate may be performed in the source gas concentration ranging from 0 to 1E21 ions/cm³ by an undoped selective epitaxial growth process.

The concentration of the landing plug poly ranges from 1E18 ions/cm³ to 5E20 ions/cm³.

The forming a spacer may include: forming a nitride film on the gate electrode; forming an oxide film on the nitride film; and spacer-etching the oxide film and the nitride film with the oxide film as a barrier.

According to an embodiment of the present invention, a semiconductor device may include: a gate electrode formed over a SOI substrate; and source/drain regions filled with a landing plug poly in a SOI body trench exposing a BOX region. An undoped selective epitaxial growth process is performed on the trench sidewalls. A physical distance between the source and the drain is increased by the undoped selective epitaxial growth process. The landing plug poly in the source/drain regions can be annealed only at a low temperature (670° C. or less).

### BRIEF DESCRIPTION OF THE DRAWINGS

FIGS. 1a to 1d are cross-sectional diagrams illustrating a conventional method for forming a floating body transistor using a SOI substrate.

FIGS. 2a to 2f are cross-sectional diagrams illustrating a method for forming a floating body transistor according to embodiments of the present invention.

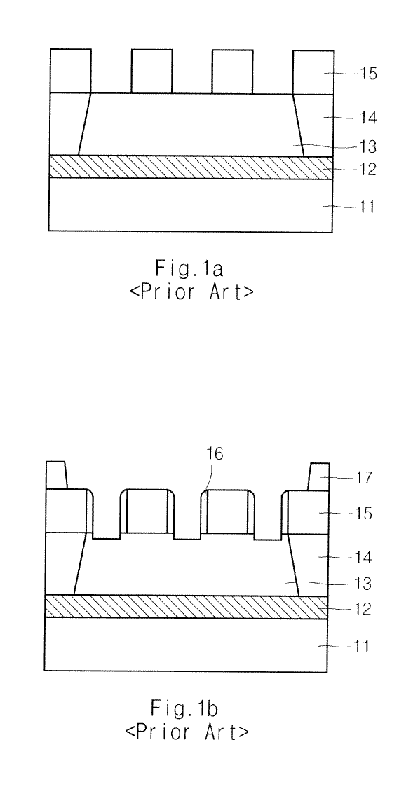

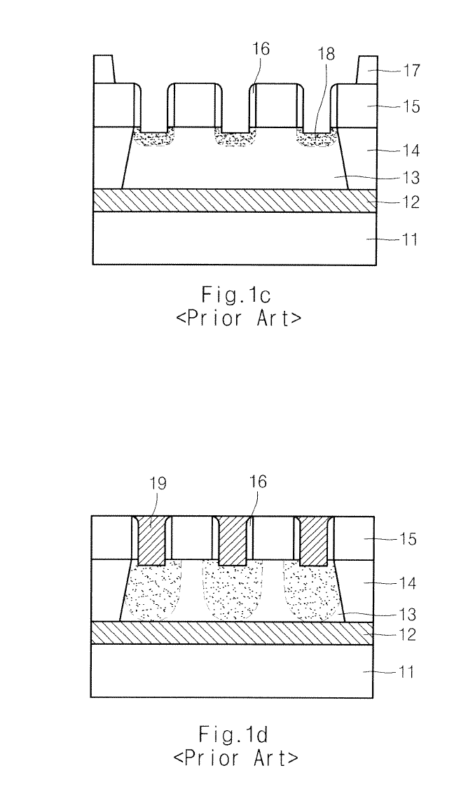

### DETAILED DESCRIPTION OF SPECIFIC EMBODIMENTS

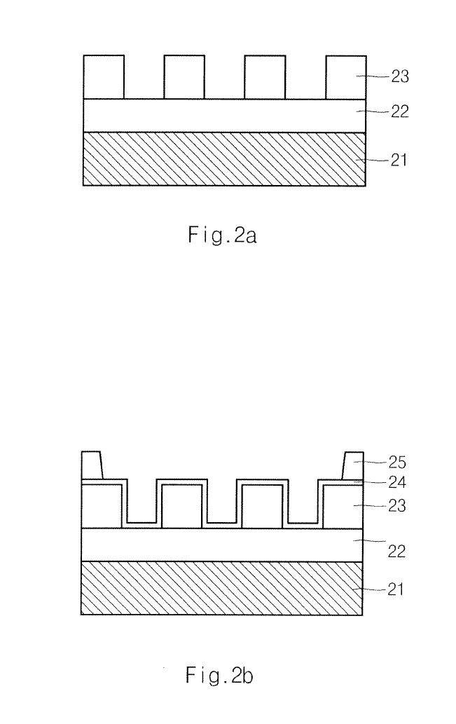

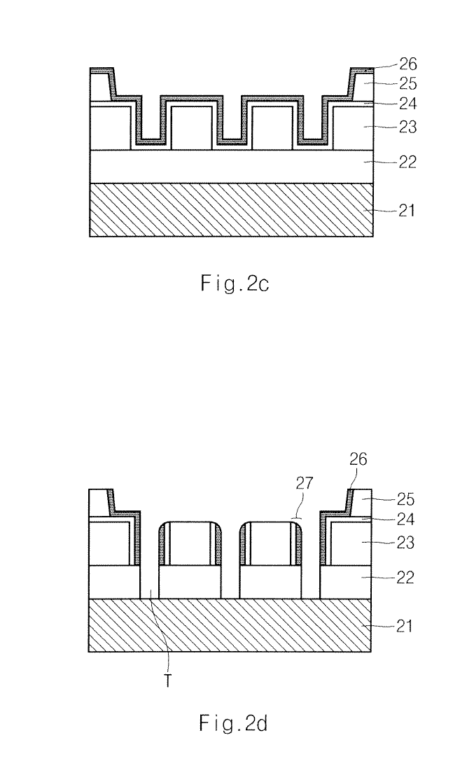

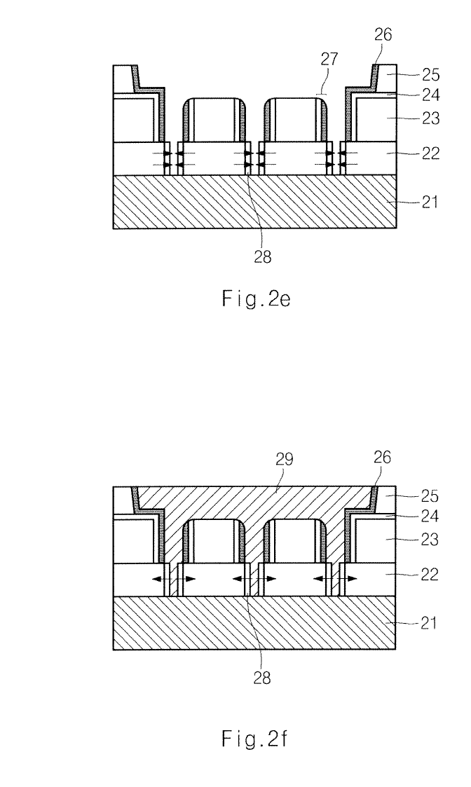

FIGS. 2a to 2f are cross-sectional diagrams illustrating a method for forming a floating body transistor according to embodiments of the present invention.

Referring to FIG. 2a, a device isolation region (not shown) and gate electrodes, one identified as gate electrode 23 are formed on an upper silicon body 22 of a SOI substrate including a lower silicon substrate (not shown), a buried insulating film (SiO2) (BOX region) 21 and the upper silicon body 22.

Specifically, a gate insulating film (not shown), a gate conductive film (not shown), a metal film (not shown) and a hard mask pattern (not shown) are sequentially formed over the SOI substrate having the device isolation region. The metal film, the gate conductive film and the gate insulating film are sequentially etched with a hard mask pattern as an etch mask, thereby forming the gate electrode 23. The gate insulating film includes an oxide film such as that formed by a thermal oxidation process. The gate conductive film may include a polysilicon film. The metal film may include a tungsten film or a tungsten silicide film. The hard mask pattern may include a nitride film.

Referring to FIG. 2b, a nitride film 24 is formed over the resulting structure of FIG. 2a. An oxide is deposited over the nitride film 24 to form an interlayer insulating (ILD) layer 25.

The interlayer insulating layer 25 where a landing plug is to be formed is etched to expose the nitride film 24.

Referring to FIG. 2c, an oxide film 26, which may be a thin film, is formed over the structure of FIG. 2b.

Referring to FIG. 2d, the oxide film 26 and the nitride film 24 are spacer-etched with the oxide film 26 as a barrier, so that a spacer 27 having a stacked structure including the oxide film 26 and the nitride film 24 is formed on sidewalls of the gate electrode 23.

The silicon substrate 22 exposed between the gate electrodes 23 is etched with the spacer 27 as an etch mask to expose the BOX region 21, thereby forming a trench T.

Generally, silicon has a smaller etching selectivity than those of the hard mask and the spacer nitride film. As a result, a Self-Aligned Contact (SAC) fail may occur when the silicon substrate 22 is etched deep into the BOX region as shown in FIG. 2d. In one potential embodiment, the spacer 27 may be formed to have a stacked structure including the nitride film 24 and the oxide film 26, which serves to maintain the SAC etching margin.

Referring to FIG. 2e, an undoped selective epitaxial growth (SEG) process is performed on the structure of FIG. 2d. That is, the selective epitaxial growth process is performed without ion-implanting impurities, thereby growing the exposed silicon substrate 22. The source gas concentration in the selective epitaxial growth process ranges from about 0 to about 1E21/cm³.

The selective epitaxial growth process grows a monocrystal silicon structure 28 on both sidewalls of the silicon substrate 22 in a horizontal direction. Since the bottom of the trench T reaches the BOX region 21, which does not support the selective epitaxial growth, silicon growing in a vertical direction does not occur.

Referring to FIG. 2f, a landing plug poly is formed over the structure of FIG. 2e, so that the grown silicon structure 28 may contact with the landing plug poly. A low temperature (670° C. or less) annealing process is performed to diffuse the junction region, thereby forming source/drain regions. The concentration of the landing plug poly ranges from about 1E18 ions/cm³ to about 5E20 ions/cm³.

That is, for junction isolation of cells, impurities are ion-implanted into the silicon substrate of the source/drain regions in the conventional art. However, in an embodiment of the present invention, the silicon substrate 22 of the corresponding region is etched and grown, and the landing plug poly is formed between grown silicone structures 28 on the box region, thereby obtaining the source/drain junction region. As a result, structures in accordance with embodiments of the present invention can prevent a punch-through phenomenon between the source and the drain without decreasing the thickness of the SOI substrate, and can also facilitate junction isolation.

Moreover, in an embodiment of the present invention, the silicon substrate 22 is etched to the BOX region 21 so that the landing plug poly may make direct contact with the BOX region 21. As a result, a high temperature annealing process is not required for junction isolation when the floating body transistor is formed in the SOI substrate.

Also, in an embodiment of the present invention, silicon structures 28 are grown on the silicon substrate 22 in the horizontal direction, and the junction region is formed in the region of the grown silicon structures 28, thereby obtaining a punch-through margin corresponding to the grown amount of the silicon structures 28.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or nonvolatile memory device. Other additions, subtractions, or modifications are obvious in view of the present disclosure and are intended to fall within the scope of the appended claims.

What is claimed is:

1. A method for manufacturing a semiconductor device, the method comprising:
etching a Silicon-On-Insulation (SOI) substrate of source/drain regions to expose a BOX region;
growing sidewalls of the etched substrate; and
filling a landing plug poly between the grown sidewalls.

2. The method according to claim 1, further comprising annealing the landing plug poly at a low temperature.

3. The method according to claim 1, wherein the growing a substrate is performed by an undoped selective epitaxial growth process.

4. The method according to claim 3, wherein the source gas concentration in the selective epitaxial growth process ranges from 0 to 1E21 ions/cm³.

5. The method according to claim 1, wherein the concentration of the landing plug poly ranges from 1E18 ions/cm³ to 5E20 ions/cm³.

6. A method for manufacturing a semiconductor device, the method comprising:
forming a gate electrode over a SOI substrate;
forming a spacer on sidewalls of the gate electrode;
etching the substrate between the gate electrodes exposed by the spacer to expose a BOX region;
growing sidewalls of the etched substrate; and
filling a landing plug poly between the grown the sidewalls.

7. The method according to claim 6, further comprising annealing the landing plug poly at a low temperature.

8. The method according to claim 6, wherein the forming a spacer comprises:
forming a nitride film over the gate electrode;
forming an oxide film over the nitride film; and
spacer-etching the oxide film and the nitride film with the oxide film as a barrier.

9. The method according to claim 6, wherein the growing sidewalls of the substrate is performed by an undoped selective epitaxial growth process.

10. The method according to claim 9, wherein the source gas concentration in the selective epitaxial growth process ranges from 0 to 1E21 ions/cm³.

11. The method according to claim 6, wherein the concentration of the landing plug poly ranges from 1E18 ions/cm³ to 5E20 ions/cm³.

12. A semiconductor device comprising:
a gate electrode formed over a SOI substrate; and
source/drain regions filled with a landing plug poly in a SOI body trench exposing a BOX region.

13. The semiconductor device according to claim 12, wherein a distance between trench sidewalls of the SOI body trench is smaller than a distance between adjacent gate electrodes.

14. The semiconductor device according to claim 13, wherein an undoped selective epitaxial growth process is performed on the trench sidewalls.

15. The semiconductor device according to claim 12, wherein the landing plug poly in the source/drain regions is annealed at a low temperature.
